(19) United States
(12) Patent Application Publication
(10) Pub. No.: US 2023/0112746 A1
(43) Pub. Date: Apr. 13, 2023

(54) HIGH MODULUS BORON-BASED CERAMICS FOR SEMICONDUCTOR APPLICATIONS

(71) Applicant: Lam Research Corporation, Fremont, CA (US)

(72) Inventors: Ananda K. BANERJI, West Linn, OR (US); Jon HENRI, West Linn, OR (US); Kapu Sirish REDDY, Portland, OR (US); Christopher Nicholas IADANZA, Tualatin, OR (US)

(21) Appl. No.: 17/904,925

(22) PCT Filed: Feb. 23, 2021
(86) PCT No.: PCT/US2021/019239

§ 371 Date: Aug. 24, 2022

Related U.S. Application Data
(60) Provisional application No. 62/980,758, filed on Feb. 24, 2020.

(51) Int. Cl. C23C 16/32; H01J 37/32; H01L 21/02; C23C 16/509; C23C 16/52; C23C 16/455

(52) U.S. Cl. CPC C23C 16/32; H01J 37/321; H01J 37/32449; H01L 21/02112; H01L 21/02274; H01L 21/02205; C23C 16/509; C23C 16/52; C23C 16/45512; C23C 16/45565; H01J 2237/3321; H01J 2237/2001; H01J 37/32816

(57) ABSTRACT

Various embodiments herein relate to methods, apparatus, and systems for depositing a boron-based ceramic film on a substrate. Advantageously, the boron-based ceramic films described herein can be formed at relatively low temperatures (e.g., about 600C or less), while still achieving very high quality materials that exhibit good mechanical strength (e.g., high hardness and Young's modulus), good etch selectivity, amorphous morphology, etc. The films herein also have low hydrogen content, low oxygen content, and low halide content. In many cases, the films may be formed through a reaction between a boron halide and a saturated or unsaturated hydrocarbon, in the presence of plasma.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing often involves tradeoffs between desired material properties and limitations. For example, many high quality materials have only been obtainable by using extremely harsh processing conditions. The harsh processing conditions have limited the applicability of such high quality materials, for example because partially fabricated semiconductor devices are not able to withstand the harsh processing conditions.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, apparatus, and systems for forming boron-based ceramic films on a semiconductor substrate. The boron-based ceramic films are high quality films with high mechanical strength (e.g., high hardness and high Young's modulus) and other favorable qualities.

In one aspect of the disclosed embodiments, a method of forming a boron-based ceramic film on a substrate is provided, the method including: (a) receiving the substrate in a reaction chamber; (b) providing a first reactant and a second reactant to the reaction chamber, the first reactant including a boron halide; (c) generating an inductively coupled plasma in the reaction chamber and reacting the first reactant with the second reactant in a plasma enhanced chemical vapor deposition reaction at a temperature of about 600° C. or less to form the boron-based ceramic film on the substrate.

In various embodiments, the boron-based ceramic film may have a hydrogen content of about 15% (atomic) or less. In these or other embodiments, the boron-based ceramic film may have a halide content of about 1% (atomic) or less. In these or other embodiments, the boron-based ceramic film may have a Young's modulus of about 175 GPa or greater. In some embodiments, the boron-based ceramic film may have an oxygen content of about 1% (atomic) or less. In these or other embodiments, the second reactant may include a saturated or unsaturated hydrocarbon. The saturated or unsaturated hydrocarbon may be the only hydrogen-bearing precursor provided to the reaction chamber. In some embodiments, no reactant provided to the reaction chamber includes both boron and hydrogen. In other words, no reactant provided to the reaction chamber is a hydrogen-containing boron precursor. Particular examples of precursors that may be excluded include borohydrides and boranes. In some embodiments, the first reactant may include BF₃ and the second reactant may include CH₄, and the boron-based ceramic film may include boron carbide having a composition of BₓC_{y}, where 2<x<4.5, and y=1. In some embodiments, the boron-based ceramic film may include boron carbide or boron nitride having a composition of BₓA_{y}, where 1<x<4.5, y=1, and A is carbon or nitrogen. In some embodiments, the boron-based ceramic film may further include tungsten and/or silicon. In some embodiments, the boron-based ceramic film may include at least one material selected from the group consisting of: boron carbide, boron nitride, boron carbonitride, tungsten borocarbide, tungsten boronitride, silicon borocarbide, silicon boronitride, and tungsten silicon borocarbide.

In various embodiments, the boron-based ceramic film may have particular properties as described herein. For instance, in some embodiments, the Young's modulus of the boron-based ceramic film may be between about 250-300 GPa. In these or other embodiments, a hardness of the boron-based ceramic film may be about 20 GPa or greater, for example 25 GPa or greater. In these or other embodiments, the hydrogen content of the boron-based ceramic film may be about 13% (atomic) or less. In these or other embodiments, the halide content of the boron-based ceramic film may be about 0.75% (atomic) or less. In these or other embodiments, a density of the boron-based ceramic film may be about 2 g/cc or greater, for example 2.2 g/cc or greater. In these or other embodiments, the boron-based ceramic film may have a boron content of about 50%/(atomic) or greater. In some such embodiments, the boron content of the boron-based ceramic film may be about 60% (atomic) or greater. In these or other embodiments, the oxygen content of the boron-based ceramic film may be about 0.5% (atomic) or less. In these or other embodiments, the boron-based ceramic film may be amorphous.

In some implementations, particular reactants and/or plasmas and/or processing conditions may be used. For example, in some embodiments, the plasma may be an inductively coupled plasma. In these or other embodiments, the first reactant may include BF₃. In these or other embodiments, the first reactant may include BC₃. In various cases, the first reactant may include BF₃ and/or BC₃. In these or other embodiments, the first reactant may include BBr₃. In these or other embodiments, the first reactant may include BI₃. In various cases, the first reactant may include BBr₃ and/or BI₃. In these or other embodiments, the second reactant may include a reactant selected from the group consisting of: methane (CH₄), ethane (C₂H₆), propane (C₃H₈), ethene (C₂H₄), and propene (C₃H₆). In some such embodiments, the second reactant may include CH₄. In these or other embodiments, the second reactant may include C₂H₆. In these or other embodiments, the second reactant may include C₃H₈. In these or other embodiments, the second reactant may include C₂H₄. In these or other embodiments, the second reactant may include C₃H₆.

In another aspect of the disclosed embodiments, an apparatus for forming a boron-based ceramic film on a substrate is provided, the apparatus including: (a) a reaction chamber; (b) a substrate support configured to support a substrate in the reaction chamber; (c) one or more inlet for introducing reactants to the reaction chamber; (d) one or more outlet for removing material from the reaction chamber; and (e) a controller having at least one processor and a memory, where the at least one processor and the memory are communicatively connected with one another, and the memory stores computer-executable instructions for controlling the at least one processor to cause any of the methods described herein.

In another aspect of the disclosed embodiments, an apparatus for forming a boron-based ceramic film on a substrate is provided, the apparatus including: (a) a reaction chamber; (b) a substrate support configured to support a substrate in the reaction chamber; (c) one or more inlet for introducing reactants to the reaction chamber; (d) one or more outlet for removing material from the reaction chamber; and (e) a controller having at least one processor and a memory, where the at least one processor and the memory are communicatively connected with one another, and the memory stores computer-executable instructions for controlling the at least one processor to cause exposing the substrate to an inductively coupled plasma to drive a plasma enhanced chemical vapor deposition reaction between a boron halide and an additional reactant to form a boron-based ceramic film on the substrate at a temperature of about 600° C. or less.

In a further aspect of the disclosed embodiments, an apparatus for forming a boron-based ceramic film on a substrate is provided, the apparatus including: (a) a reaction chamber; (b) a substrate support configured to support the substrate in the reaction chamber; (c) one or more inlet for introducing reactants to the reaction chamber; (d) one or more outlet for removing material from the reaction chamber; (e) a plasma generator configured to generate a plasma in the reaction chamber, the plasma being an inductively coupled plasma; and (f) a controller having at least one processor and a memory, where the at least one processor and the memory are communicatively connected with one another, and the memory stores computer-executable instructions for controlling the at least one processor to cause: (i) receiving the substrate in the reaction chamber, (ii) flowing a first reactant and a second reactant into the reaction chamber, and (iii) generating the plasma in the reaction chamber and reacting the first reactant with the second reactant at a temperature of about 600° C. or less to form the boron-based ceramic film on the substrate, where the boron-based ceramic film has: (1) a Young's modulus of about 175 GPa or greater, (2) a hydrogen content of about 15% (atomic) or less, and (3) a halide content of about 1% (atomic) or less.

These and other aspects are described further below with reference to the drawings.

### BRIEF DESCRIPTION OF THE DRAWINGS

FIG. 1 is a flowchart describing a method of forming a boron-based ceramic material according to various embodiments.

FIG. 2 illustrates a reaction chamber that may be used to deposit a boron-based ceramic material according to various embodiments.

FIG. 3 depicts a multi-station tool that may be used to deposit a boron-based ceramic material according to various embodiments.

FIG. 4 illustrates a processing system having multiple reaction chambers, each having multiple stations therein, which may be used to deposit a boron-based ceramic material according to various embodiments.

FIG. 5 shows experimental results (FTIR) examining the composition of a boron-based ceramic material deposited according to an embodiment herein.

FIGS. 6A-6F and 7A-7F show experimental results (XPS) examining the bonding states present in boron-based ceramic materials deposited according to certain embodiments herein.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Conventional techniques for forming boron-based ceramic materials present several challenges that make it difficult to incorporate such techniques into semiconductor fabrication schemes. For example, such conventional techniques (1) take place at very high temperatures, and/or (2) result in low quality, low mechanical strength materials. Example high temperature techniques may involve, e.g., high temperature furnace reactions, E-beam reactions, hot filament activation, combustion synthesis reactions, etc. These techniques are problematic because many semiconductor fabrication schemes have a limited thermal budget, meaning that the substrates/materials can be damaged if exposed to excessive heating. Further, these high temperature techniques typically result in ceramic materials that are highly crystalline, which makes them unsuitable for hardmask applications. As such, it is desirable to keep processing temperatures low. However, conventional low temperature techniques for forming boron-based ceramics have resulted in low quality materials that do not exhibit the desired properties such as etch selectivity and mechanical strength.

The conventional low temperature techniques utilize plasma enhanced chemical vapor deposition (PECVD) to form boron-based ceramics (e.g., boron carbide or boron nitride) using diborane (B₂H₆) as a reactant. Processing temperatures are typically <550° C., which is appropriate for various semiconductor applications. However, due to the use of diborane, which has a substantial hydrogen content, there is a high degree of hydrogen incorporation into the film. Often, such films are >20% hydrogen. Unless stated otherwise, film compositions recited herein as percentages are intended to reflect atomic percentages.

Further, such conventional low temperature films tend to be low density and exhibit inferior mechanical properties (e.g., hardness <20 GPa, Young's modulus <150 GPa), which result in unacceptably low etch selectivity. These inferior properties make the conventional low temperature boron-based ceramic materials undesirable or even unsuitable for use as a hardmask or other applications in integration that require high mechanical strength properties.

Surprisingly, the inventors have identified new low temperature deposition techniques that may be used to form high quality boron-based ceramic materials having superior properties such as high etch selectivity, high mechanical strength, stable thermal and optical properties, etc. The resulting boron-based ceramic materials are particularly well suited as hardmask materials, though they may be used in a variety of different semiconductor applications, as desired. As used herein, low temperature techniques are those that occur at about 600° C. or less.

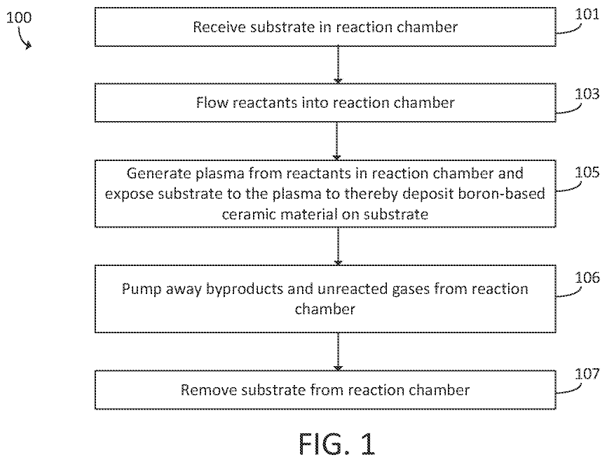

FIG. 1 is a flowchart that describes a method 100 of depositing a boron-based ceramic material according to various embodiments herein. The method 100 begins at operation 101, where a substrate is received in a reaction chamber. The reaction chamber is a PECVD chamber configured to generate an inductively coupled plasma. The substrate is typically loaded onto a substrate holder in the reaction chamber. Next, at operation 103, reactants are flowed into the reaction chamber. In many cases the reactants include (1) at least one boron halide, and (2) at least one saturated or unsaturated hydrocarbon. Examples of boron halides include, e.g., boron trifluoride (BF₃), boron trichloride (BCl₃), boron tribromide (BBr₃), and boron triiodide (BI₃). Examples of saturated hydrocarbons include, e.g., methane (CH₄), ethane (C₂H₆), propane (C₃H₈), butane (C₃H₁₀), etc. Examples of unsaturated hydrocarbons include, e.g., ethene (C₂H₄), propene (C₃H₆), butene (C₄H₈), etc. Generally, the hydrocarbon reactants used herein are small hydrocarbon molecules similar to those listed above (e.g., CₓH_{y}, where x≤4). These reactants may be used to form ceramic films that include boron and carbon, such as BC, WBC, BCN, SiBC, and SiWBC. In cases where the ceramic film includes nitrogen, a nitrogen-containing reactant such as NH₃ may be used. In cases where the ceramic film includes tungsten, a tungsten-containing reactant may be used. In cases where the ceramic film includes silicon, a silicon-containing reactant may be used. In another example the ceramic film is BN, and the reactants used to form the ceramic film include a boron halide and NH₃.

In various embodiments, the reactants do not include diborane or any other boron- and hydrogen-containing reactant. In other words, the reactants do not include hydrogen-containing boron precursors. Particular examples of precursors that may be excluded include borohydrides and boranes. In many cases, no hydrogen-containing reactants are provided to the reaction chamber, except for the hydrocarbon reactant. Excluding such reactants minimizes the amount of hydrogen that is incorporated into the boron-based ceramic film, for example by minimizing the amount of hydrogen introduced to the reaction chamber, and by ensuring that most of the hydrogen that is introduced to the reaction chamber is easily and efficiently reacted and removed from the chamber (e.g., as a gas phase reaction product) before it is incorporated into the growing film. As such, the resulting boron-based ceramic film has a notably lower hydrogen content compared to conventional low temperature boron-based ceramic films. For instance, while conventional low temperature boron-based ceramic films formed from diborane always have a hydrogen content >20%, films produced according to the embodiments herein have a lower hydrogen content, e.g., <15%, <14%, or <13%. In one example presented below in the Experimental section, the techniques described herein are used to produce boron carbide having a hydrogen content of just 12.5%. The reduction in hydrogen content compared to conventional techniques/films results in substantial improvements in film properties such as etch selectivity, hardness, and Young's modulus.

Returning to FIG. 1, the method continues with operation 105, where plasma is generated from the reactants in the reaction chamber and the substrate is exposed to the plasma. The boron fluoride reacts with the hydrocarbon to form a boron-based ceramic material that is deposited on the substrate. At operation 106, byproducts and unreacted gases are pumped away from the reaction chamber. Operations 103, 105, and 106 may overlap in time, and the duration of each operation may be selected to produce the boron-based ceramic material at a desired thickness. Removing the byproducts from the reaction chamber in operation 106 promotes formation of a boron-based ceramic material at a desired composition, for example having low amounts of impurities as described herein. After the boron-based ceramic material is deposited on the substrate, the plasma is extinguished and the substrate is removed from the reaction chamber in operation 107. The method can then be repeated on a different substrate.

A number of example reactions are provided below, though the embodiments herein are not intended to be limited to the listed examples.

4BF₃(g)+3CH₄(g)→B₄C(s)+8HF(g)+2CH₂F₂(g) Reaction 1

4BCl₃(g)+3CH₄(g)→B₄C(s)+8HCl(g)+2CH₂Cl₂(g) Reaction 2

4BBr₃(g)+3CH₄(g)→B₄C(s)+8HBr(g)+2CH₂Br₂(g) Reaction 3

4BhI₃(g)+3CH₄(g)→B₄C(s)+8HI(g)+2CH₂I₂(g) Reaction 4

While Reactions 1-4 relate to particular embodiments in which a boron halide reacts with methane to produce B₄C, a hydrogen halide, and a dihalomethane, the embodiments are not so limited. In various embodiments, other fluorocarbons may be produced (alternatively or in addition to the products listed above). Such fluorocarbons may have the formula CFₓH₄₋ₓ.

In another example, the ceramic film that is formed is BN. An example reaction that may be used is provided below;

BX₃+NH₃+H₂→BN+NH₄X+HX, where X is a halogen. Reaction 5

The stoichiometry may be balanced as appropriate for a desired application, for example to produce a boron- and nitrogen-containing ceramic material having a particular composition. Alternative or additional reaction products may be produced in some cases.

In another example, the ceramic film that is formed is BCN. An example reaction that may be used is provided below:

BX₃+CH₄+NH₃→BCₓN_{y+}+NH₄X+CXₓH₄₋ₓ+HX, where X is a halogen. Reaction 6

The stoichiometry may be balanced as appropriate for a desired application, for example to produce BCN having a particular composition. Alternative or additional reaction products may be produced in some cases.

One advantage of the disclosed techniques is that there is very little reaction of the boron-based ceramic material with the byproducts of the deposition process. This allows the byproducts to be cleanly eliminated from the reaction chamber before they can become trapped in the growing film. This clean byproduct removal results in film having a low degree of impurities, both with respect to hydrogen and with respect to the halogen introduced from the boron halide reactant.

Another advantage of the disclosed techniques is that the composition of the boron-based ceramic material can be closely controlled through careful stoichiometric balancing and control of the relative reactant flow rates. In many cases, the reactant flow rates are controlled to produce a boron-containing ceramic material that has two to four times as many boron atoms as other atoms.

For example, when forming boron carbide, the reactant flows may be controlled to produce boron carbide having about two to four times as many boron atoms as carbon atoms.

It is understood that the resulting ceramic materials do not necessarily have perfect stoichiometric balance. More generally, in some cases the boron-containing materials produced herein may have a formula of BₓA_{y}, where 2<x<4.5, y=1, and A is an element such as carbon or nitrogen. In some such cases, x may be at least about 2.25, at least about 2.5, at least about 2.75, at least about 3, at least about 3.25, at least about 3.5, or at least about 3.75. In these or other cases, x may be about 4.4 or less, about 4.3 or less, about 4.2 or less, or about 4.1 or less. Any of the minimum and maximum values described for x may be combined as desired for a particular application (e.g., 2.3<x<4.1, etc.). As mentioned, in some cases the boron-containing ceramic material may include one or more further element such as tungsten and/or silicon in addition to the carbon and/or nitrogen.

In various embodiments, the boron-containing ceramic material may be doped with nitrogen and/or phosphorus. The flow rates of the reactants may be controlled relative to one another in order to produce the desired stoichiometry.

As mentioned above, in many cases the reactants for forming the boron-based ceramic material include (1) at least one boron halide, and (2) at least one saturated or unsaturated hydrocarbon. These reactants are appropriate for forming ceramic materials that include both boron and carbon. In embodiments where the boron-based ceramic material includes other elements such as nitrogen, tungsten, or silicon, the reactants provided to the reaction chamber will also include such elements. In a particular embodiment where the boron-based ceramic material is BN, the saturated or unsaturated hydrocarbon may be replaced by a nitrogen-containing reactant such as NH₃.

Boron-containing ceramic materials having the disclosed compositions and formed according to the embodiments herein show very favorable properties such as amorphous morphology, low hydrogen content, low halide content, high etch selectivity, high density, high hardness, high Young's modulus, and stable thermal and optical properties. These properties make the boron-containing ceramic materials useful as hardmasks.

Generally, amorphous materials are preferred to crystalline materials for hardmask applications. Amorphous materials exhibit better patterning, with smoother features and less roughness. Low hydrogen content promotes a high degree of etch selectivity as well as film stability. With regard to etch selectivity, it is desirable that the ceramic material is relatively resistant to the etch chemistry used for a particular application (e.g., fluorocarbon- or chlorine-based etch chemistry) as compared to the other materials that are desired to be etched (e.g., dielectric material). Etch selectivity is also affected by film density, with denser ceramic films tending to exhibit a lower etch rate and a correspondingly higher etch selectivity while such films are being used as hardmasks. Low halide content is also desired, for example to prevent diffusion of the halide into underlying or surrounding material where the halide could cause damage. It is also desirable that the boron-containing ceramic material has high mechanical strength, as indicated by a high Young's modulus, as well as a high degree of hardness. Together, these properties ensure a high quality hardmask material.

As mentioned above, the reactants and reactant flow rates may be selected to produce a desired stoichiometric balance in the resulting boron-containing ceramic material. Further, various other processing conditions may be controlled during deposition. In some embodiments, a pressure within the reaction chamber may be maintained between about 50-1000 mTorr (e.g., 6.5-135 Pa), or between about 50-200 mTorr (e.g., 6.5-27 Pa). In some cases, an RF power used to generate the plasma may be between about 500-2000 W. In some cases, dual frequency RF may be used, for example with a first frequency at about 13.5 MHz and a second frequency at about 400 kHz. Different RF power levels may be provided for each frequency. In a particular example, the plasma may be pulsed at a duty cycle between about 5-15%, for example about 10%. The plasma may be pulsed at a frequency between about 200-800 Hz, for example about 500 Hz. The substrate may be exposed to plasma for a duration sufficient to form the boron-containing ceramic material at a desired thickness. Example thicknesses for hardmask applications may be between about 500-5000 angstrom, for example between about 500-1000 angstrom. Example plasma exposure durations may be as short as several seconds and as long as several minutes, depending on the deposition rate and desired thickness. During deposition, the substrate may be supported on a substrate support, which may be temperature controlled. In certain cases, the substrate support may be maintained at a temperature between about 400-650° C. The use of plasma energy to drive the reaction between the reactants permits the substrate to remain at relatively low temperatures during processing. In many cases, the substrate temperature remains between about 200-600° C. As such, the thermal load on the substrate is relatively low, especially in comparison to the high temperature deposition techniques described above. In certain embodiments, one or more precursors may be heated to ensure adequate volatilization of the precursors.

The plasma used in the techniques described herein is an inductively coupled plasma. Inductively coupled plasmas are sufficiently high energy that they can effectively and efficiently break up the reactants into smaller, more favorable forms. By comparison, other types of plasma such as capacitively coupled plasma are not sufficiently high energy to cause the desired reactant dissociation/reactions. In certain embodiments, capacitively coupled plasma or other type of plasma may be used in addition to the inductively coupled plasma.

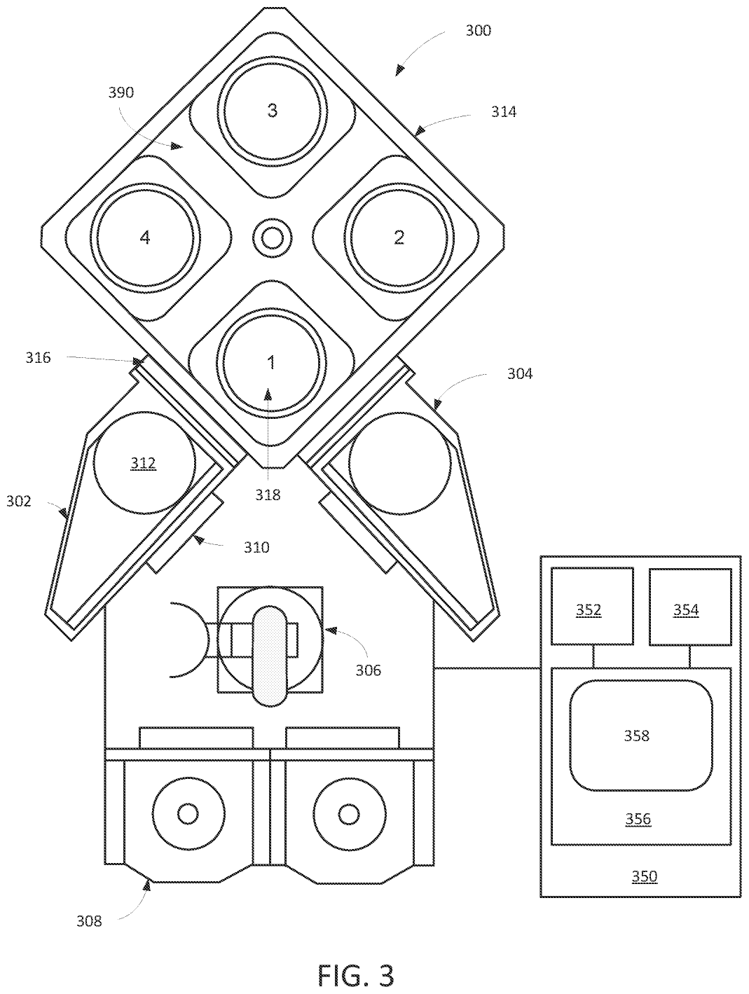

In some embodiments, the boron-based ceramic film may be deposited in distinct steps, with different steps occurring at different locations. For instance, FIG. 3 (described further below) illustrates a multi-station processing tool 300. In some embodiments, the boron-based ceramic film is deposited in two or more stations, with a portion of the film being deposited at each station. This multi-station deposition approach may be used to average-out non-uniformities in the film, for example non-uniformities that arise from deposition in a particular process station.

Apparatus

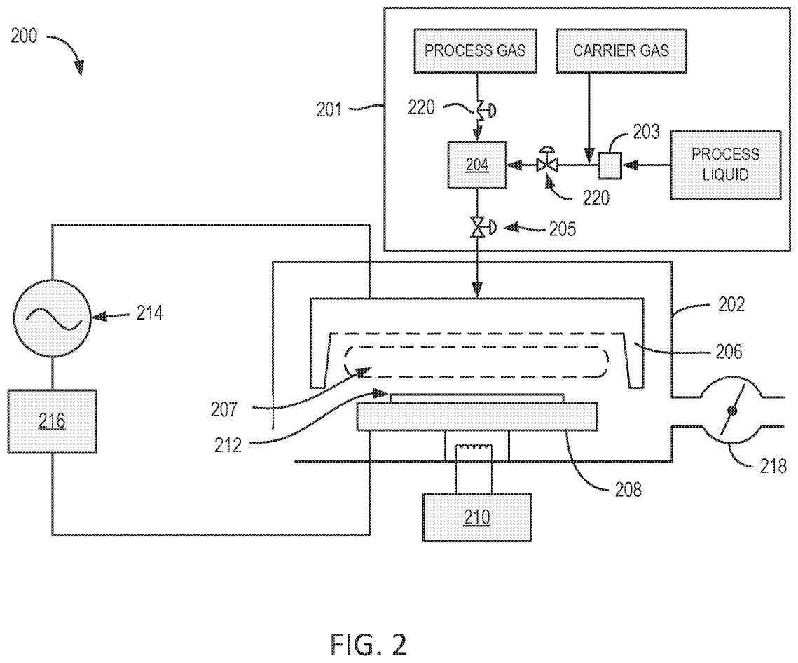

FIG. 2 schematically shows an embodiment of a process station 200 that may be used to deposit boron-containing ceramic material using plasma enhanced chemical vapor deposition (PECVD) according to various embodiments herein. The process station 200 may also be used for other purposes such as chemical vapor deposition and atomic layer deposition. For simplicity, the process station 200 is depicted as a standalone process station having a process chamber body 202 for maintaining a low-pressure environment. However, it will be appreciated that a plurality of process stations 200 may be included in a common process tool environment. Further, it will be appreciated that, in some embodiments, one or more hardware parameters of process station 200, including those discussed in detail below, may be adjusted programmatically by one or more computer controllers.

Process station 200 fluidly communicates with reactant delivery system 201 for delivering process gases to a distribution showerhead 206. In this example, reactant delivery system 201 includes a mixing vessel 204 for blending and/or conditioning process gases for delivery to showerhead 206. One or more mixing vessel inlet valves 220 may control introduction of process gases to mixing vessel 204. In certain other examples, the process gases may remain separate until delivery to the showerhead 206 or the process chamber body 202. Similarly, a showerhead inlet valve 205 may control introduction of process gasses to the showerhead 206. In various embodiments, certain process gases may be delivered from a cylinder that includes monolith carbon adsorbent pucks (not shown). This delivery system may be particularly useful for providing safe delivery of corrosive gases such as BF₃.

Some reactants may be stored in liquid form prior to vaporization at and subsequent delivery to the process station. For example, the embodiment of FIG. 2 includes a vaporization point 203 for vaporizing liquid reactant to be supplied to mixing vessel 204. In some embodiments, vaporization point 203 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 203 may be heat traced. In some examples, mixing vessel 204 may also be heat traced. In one non-limiting example, piping downstream of vaporization point 203 has an increasing temperature profile extending from approximately 100° C. to approximately 150° C. at mixing vessel 204.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 203. In one scenario, a liquid injector may be mounted directly to mixing vessel 204. In another scenario, a liquid injector may be mounted directly to showerhead 206.

In some embodiments, a liquid flow controller upstream of vaporization point 203 may be provided for controlling a mass flow of liquid for vaporization and delivery to process station 200. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Inert gas may be co-flowed into the chamber along with one or more of the reactants. Example inert gases include He, Ar, H₂, and N₂. The inert gas may flow at a rate between about 500-10,000 sccm. Inert gases may be useful for a number of reasons, for example to promote uniform delivery of reactant gases, to maintain the plasma, to accomplish uniform film growth across the substrate surface, and to promote removal of byproducts from the substrate surface.

Showerhead 206 distributes process gases toward substrate 212. The process gases can include any of those described herein, including but not limited to boron halides, saturated and unsaturated hydrocarbons, silicon-containing reactants, tungsten-containing reactants, NH₃ and other nitrogen-containing reactants, inert gases, etc. In the embodiment shown in FIG. 2, substrate 212 is located beneath showerhead 206, and is shown resting on a pedestal 208. It will be appreciated that showerhead 206 may have any suitable shape, and may have any suitable number and arrangement of ports for distributing processes gases to substrate 212.

In some embodiments, a microvolume 207 is located beneath showerhead 206. Performing a deposition process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 208 may be raised or lowered to expose substrate 212 to microvolume 207 and/or to vary a volume of microvolume 207. For example, in a substrate transfer phase, pedestal 208 may be lowered to allow substrate 212 to be loaded onto pedestal 208. During a deposition process phase, pedestal 208 may be raised to position substrate 212 within microvolume 207. In some embodiments, microvolume 207 may completely enclose substrate 212 as well as a portion of pedestal 208 to create a region of high flow impedance during a deposition process.

Optionally, pedestal 208 may be lowered and/or raised during portions the deposition process to modulate process pressure, reactant concentration, etc., within microvolume 207. In one scenario where process chamber body 202 remains at a base pressure during the deposition process, lowering pedestal 208 may allow microvolume 207 to be evacuated. Example ratios of microvolume to process chamber volume include, but are not limited to, volume ratios between 1:200 and 1:10. It will be appreciated that, in some embodiments, pedestal height may be adjusted programmatically by a suitable computer controller.

In another scenario, adjusting a height of pedestal 208 may allow a plasma density to be varied during plasma activation and/or treatment cycles included in the deposition process. At the conclusion of the deposition process phase, pedestal 208 may be lowered during another substrate transfer phase to allow removal of substrate 212 from pedestal 208.

While the example microvolume variations described herein refer to a height-adjustable pedestal, it will be appreciated that, in some embodiments, a position of showerhead 206 may be adjusted relative to pedestal 208 to vary a volume of microvolume 207. Further, it will be appreciated that a vertical position of pedestal 208 and/or showerhead 206 may be varied by any suitable mechanism within the scope of the present disclosure. In some embodiments, pedestal 208 may include a rotational axis for rotating an orientation of substrate 212. It will be appreciated that, in some embodiments, one or more of these example adjustments may be performed programmatically by one or more suitable computer controllers.

Returning to the embodiment shown in FIG. 2, showerhead 206 and pedestal 208 electrically communicate with RF power supply 214 and matching network 216 for powering a plasma. In some embodiments, the plasma energy may be controlled by controlling one or more of a process station pressure, a gas concentration, an RF source power, an RF source frequency, and a plasma power pulse timing. For example, RF power supply 214 and matching network 216 may be operated at any suitable power to form a plasma having a desired composition of radical species. Examples of suitable powers are included above. Likewise, RF power supply 214 may provide RF power of any suitable frequency. In some embodiments, RF power supply 214 may be configured to control high- and low-frequency RF power sources independently of one another. Example low-frequency RF frequencies may include, but are not limited to, frequencies between 50 kHz and 200 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 208 may be temperature controlled via heater 210. Further, in some embodiments, pressure control for deposition process station 200 may be provided by butterfly valve 218. As shown in the embodiment of FIG. 2, butterfly valve 218 throttles a vacuum provided by a downstream vacuum pump (not shown). However, in some embodiments, pressure control of process station 200 may also be adjusted by varying a flow rate of one or more gases introduced to process station 200.

FIG. 3 shows a schematic view of an embodiment of a multi-station processing tool 300 with an inbound load lock 302 and an outbound load lock 304, either or both of which may comprise a remote plasma source. A robot 306, at atmospheric pressure, is configured to move wafers from a cassette loaded through a pod 308 into inbound load lock 302 via an atmospheric port 310. A wafer is placed by the robot 306 on a pedestal 312 in the inbound load lock 302, the atmospheric port 310 is closed, and the load lock is pumped down. Where the inbound load lock 302 comprises a remote plasma source, the wafer may be exposed to a remote plasma treatment in the load lock prior to being introduced into a processing chamber 314. Further, the wafer also may be heated in the inbound load lock 302 as well, for example, to remove moisture and adsorbed gases. Next, a chamber transport port 316 to processing chamber 314 is opened, and another robot (not shown) places the wafer into the reactor on a pedestal of a first station shown in the reactor for processing. While the embodiment depicted in FIG. 3 includes load locks, it will be appreciated that, in some embodiments, direct entry of a wafer into a process station may be provided.

The depicted processing chamber 314 comprises four process stations, numbered from 1 to 4 in the embodiment shown in FIG. 3. Each station has a heated pedestal (shown at 318 for station 1), and gas line inlets. It will be appreciated that in some embodiments, each process station may have different or multiple purposes. While the depicted processing chamber 314 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 3 also depicts an embodiment of a wafer handling system 390 for transferring wafers within processing chamber 314. In some embodiments, wafer handling system 390 may transfer wafers between various process stations and/or between a process station and a load lock. It will be appreciated that any suitable wafer handling system may be employed. Non-limiting examples include wafer carousels and wafer handling robots. FIG. 3 also depicts an embodiment of a system controller 350 employed to control process conditions and hardware states of process tool 300. System controller 350 may include one or more memory devices 356, one or more mass storage devices 354, and one or more processors 352. Processor 352 may include a CPU or computer, analog and/or digital input/output connections, stepper motor controller boards, etc.

In some embodiments, system controller 350 controls all of the activities of process tool 300. System controller 350 executes system control software 358 stored in mass storage device 354, loaded into memory device 356, and executed on processor 352. System control software 358 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 300. System control software 358 may be configured in any suitable way. For example, various process tool component subroutines or control objects may be written to control operation of the process tool components necessary to carry out various process tool processes in accordance with the disclosed methods. System control software 358 may be coded in any suitable computer readable programming language.

In some embodiments, system control software 358 may include input/output control (IOC) sequencing instructions for controlling the various parameters described above. For example, each phase of a PECVD process may include one or more instructions for execution by system controller 350. The instructions for setting process conditions for a PECVD process phase may be included in a corresponding PECVD recipe phase. In some embodiments, the PECVD recipe phases may be sequentially arranged, so that all instructions for a PECVD process phase are executed concurrently with that process phase.

Other computer software and/or programs stored on mass storage device 354 and/or memory device 356 associated with system controller 350 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 318 and to control the spacing between the substrate and other parts of process tool 300.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 350. The user interface may include a display screen, graphical software displays of the apparatus and/or process conditions, and user input devices such as pointing devices, keyboards, touch screens, microphones, etc.

In some embodiments, parameters adjusted by system controller 350 may relate to process conditions. Non-limiting examples include process gas composition and absolute and relative flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 350 from various process tool sensors. The signals for controlling the process may be output on the analog and digital output connections of process tool 300. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the VECTOR® product family, the SPEED® product family, the FLEX® product family, and/or the SEQUEL® product family, each available from Lam Research Corp., of Fremont, Calif., or any of a variety of other commercially available processing systems. Two or more of the stations may perform the same functions. Similarly, two or more stations may perform different functions. Each station can be designed/configured to perform a particular function/method as desired.

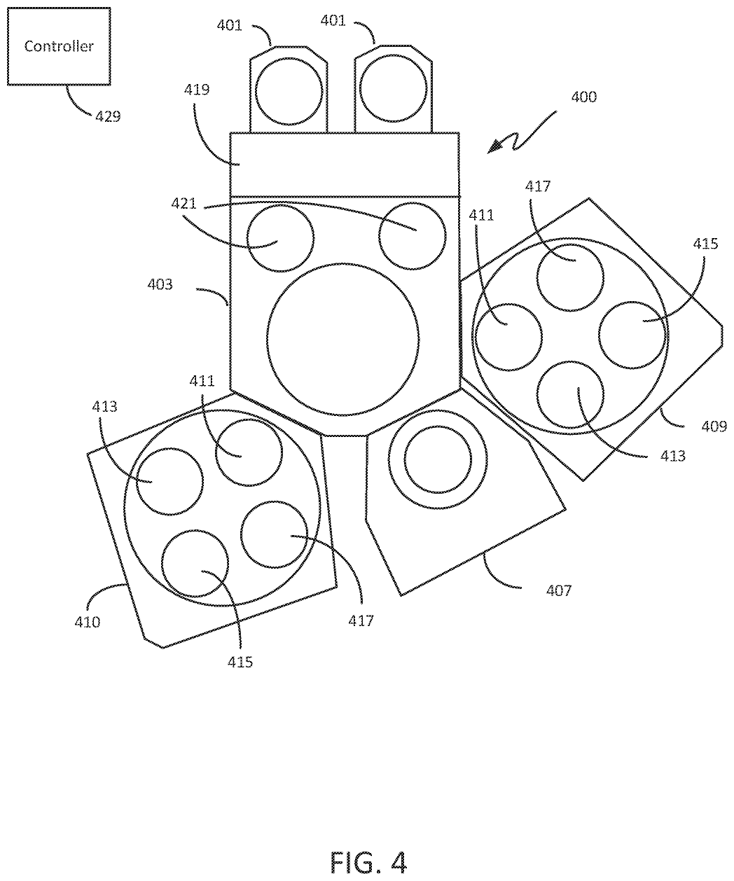

FIG. 4 is a block diagram of a processing system suitable for conducting thin film deposition processes in accordance with certain embodiments. The system 400 includes a transfer module 403. The transfer module 403 provides a clean, pressurized environment to minimize risk of contamination of substrates being processed as they are moved between various reactor modules. Mounted on the transfer module 403 are two multi-station reactors 409 and 410, each capable of performing atomic layer deposition (ALD) and/or chemical vapor deposition (CVD) according to certain embodiments. Reactors 409 and 410 may include multiple stations 411, 413, 415, and 417 that may sequentially or non-sequentially perform operations in accordance with disclosed embodiments. The stations may include a heated pedestal or substrate support, one or more gas inlets or showerhead or dispersion plate.

Also mounted on the transfer module 403 may be one or more single or multi-station modules 407 capable of performing plasma or chemical (non-plasma) pre-cleans, or any other processes described in relation to the disclosed methods. The module 407 may in some cases be used for various treatments to, for example, prepare a substrate for a deposition process. The module 407 may also be designed/configured to perform various other processes such as etching or polishing. The system 400 also includes one or more wafer source modules 401, where wafers are stored before and after processing. An atmospheric robot (not shown) in the atmospheric transfer chamber 419 may first remove wafers from the source modules 401 to loadlocks 421. A wafer transfer device (generally a robot arm unit) in the transfer module 403 moves the wafers from loadlocks 421 to and among the modules mounted on the transfer module 403.

In various embodiments, a system controller 429 is employed to control process conditions during deposition. The controller 429 will typically include one or more memory devices and one or more processors. A processor may include a CPU or computer, analog and/or digital input/output connections, stepper motor controller boards, etc.

The controller 429 may control all of the activities of the deposition apparatus. The system controller 429 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 429 may be employed in some embodiments.

Typically there will be a user interface associated with the controller 429. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the reactant flow and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 429. The signals for controlling the process are output on the analog and digital output connections of the deposition apparatus 400.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 429 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 429, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### EXPERIMENTAL

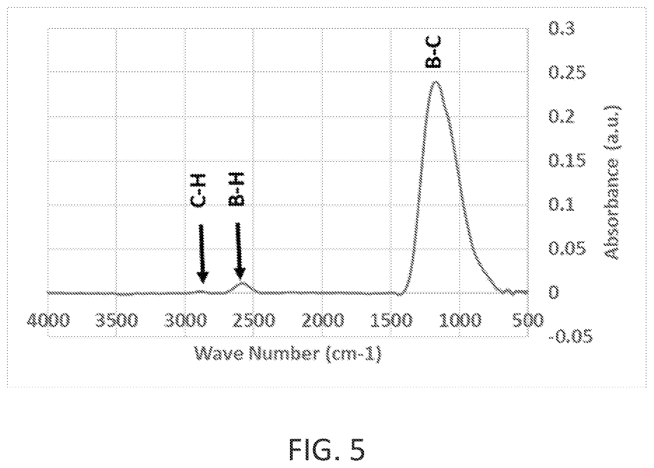

FIG. 5 depicts experimental results from a Fourier-transform infrared spectroscopy analysis (FTIR) of a boron-containing ceramic film deposited according to an embodiment herein. In this example, the boron-containing ceramic film is boron carbide. For the sake of clarity, the boron carbide film analyzed in connection with FIG. 5 is referred to as “boron carbide film 1”. The reactants used to form the boron carbide film 1 included BF₃ and CHa, as well as inert gases. The flow rates of these reactants were carefully controlled to achieve a particular ratio of B:C in the resulting film, described further below. Upon exposure to appropriate plasma conditions at a temperature of about 600° C., the BF₃ and CH₄ reacted with one another to form boron carbide according to Reaction 1, above. As shown in Reaction 1, gaseous HF and CH₂F₂ were also produced, and were efficiently removed from the reaction chamber through a vacuum connection. Additional reaction products may also have been produced.

The FTIR analysis sheds light on what type of bonds are present in boron carbide film 1, as well as their relative abundance. The results in FIG. 5 show substantial B—C bonding at a wave number of approximately 1200 (cm¹). This suggests a high degree of boron-carbon bonds in the analyzed film. FIG. 5 also shows a small amount of B—H bonding at a wave number of approximately 2600 (cm¹), and a very small amount of C—H bonding at a wave number of approximately 2900 (cm¹). This suggests a small amount of boron-hydrogen bonding and a very small amount of carbon-hydrogen bonding within the analyzed film. Further, no B—O bonding was observed. Because the B—C peak is much stronger than the other peaks combined, it is clear that the boron carbide film 1 was substantially composed of B—C bonds. From these results, it was estimated that the hydrogen content of the film was about 4% or less.

The boron carbide film 1 analyzed in connection with FIG. 5 was also subjected to a Rutherford backscattering analysis (RBS) and hydrogen forward scattering spectrometry (HFS) to more precisely characterize the composition of the film. The results are shown in Table 1, below.

TABLE 1

| B (%) | C (%) | H (%) | O (%) | F (%) |
|---|---|---|---|---|
| 60.6 | 25.8 | 12.5 | 0.4 | 0.7 |

The RBS/HFS results shown in Table 1 generally match the (less precise) FTIR results described in relation to FIG. 5. While the precise hydrogen content listed in Table 1 (e.g., 12.5% H) is higher than the rough hydrogen content estimated from the data in FIG. 5 (e.g., 4% H), the precise hydrogen content is still understood to be quite low. Specifically, the boron carbide film 1 has notably less hydrogen compared to boron carbide films deposited according to conventional low temperature techniques (e.g., using diborane as a reactant). The conventional diborane-based techniques typically produce films having at least about 20% hydrogen. As described above, the relatively high levels of hydrogen in the conventional low temperature boron-based ceramic films lead to inferior qualities such as high etch rate and correspondingly poor etching selectivity, low mechanical strength (e.g., low hardness and low Young's modulus), etc.

Table 1 also shows that the boron carbide film 1 had very low oxygen and fluorine contents. Low oxygen content is desirable because it means that the film does not oxidize or absorb moisture easily. This ensures that the film remains stable over time. In this example, the FTIR queue time was 4 weeks. Low fluorine (or other halide) content is desirable because it reduces the risk that the fluorine (or other halide) could migrate to other portions of the device (e.g., underlying or overlying layers), where it could cause damage.

Further x-ray diffraction analysis (XRD) of the boron carbide film 1 showed that the film was amorphous. No signs of crystallinity were present. Moreover, the film showed good adhesion to the underlying layer.

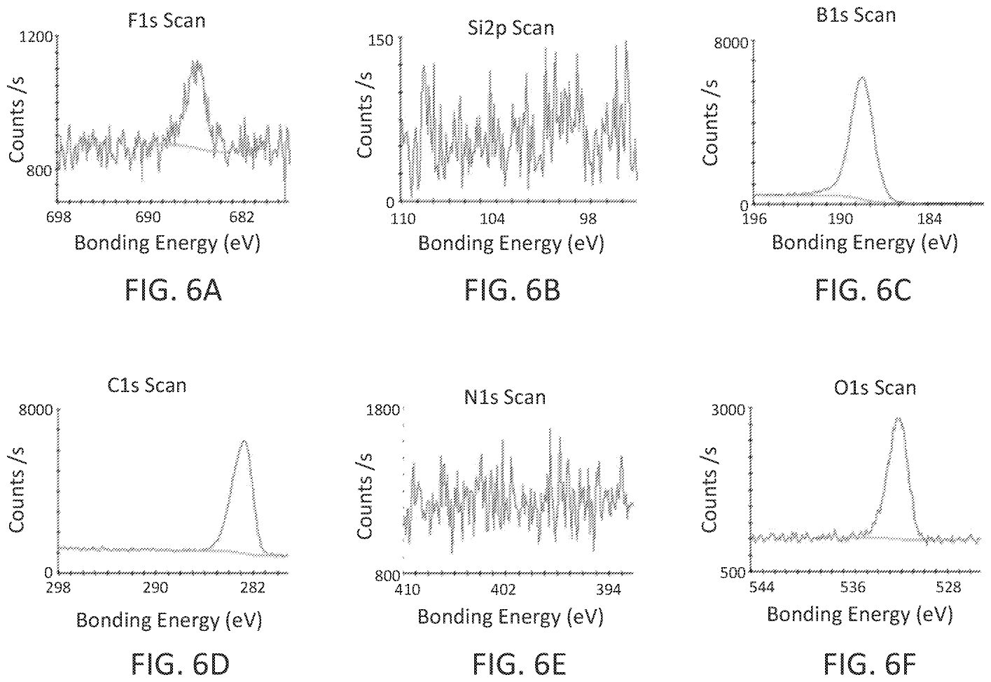

FIGS. 6A-6F illustrate x-ray photoelectron spectroscopy (XPS) results related to the boron carbide film 1 described in relation to FIG. 5 and Table 1. As noted above, the boron carbide film 1 was deposited at a temperature of about 600° C. FIG. 6A shows the fluorine is scan, FIG. 6B shows the silicon 2p scan, FIG. 6C shows the boron is scan, FIG. 6D shows the carbon is scan, FIG. 6E shows the nitrogen is scan, and FIG. 6F shows the oxygen is scan.

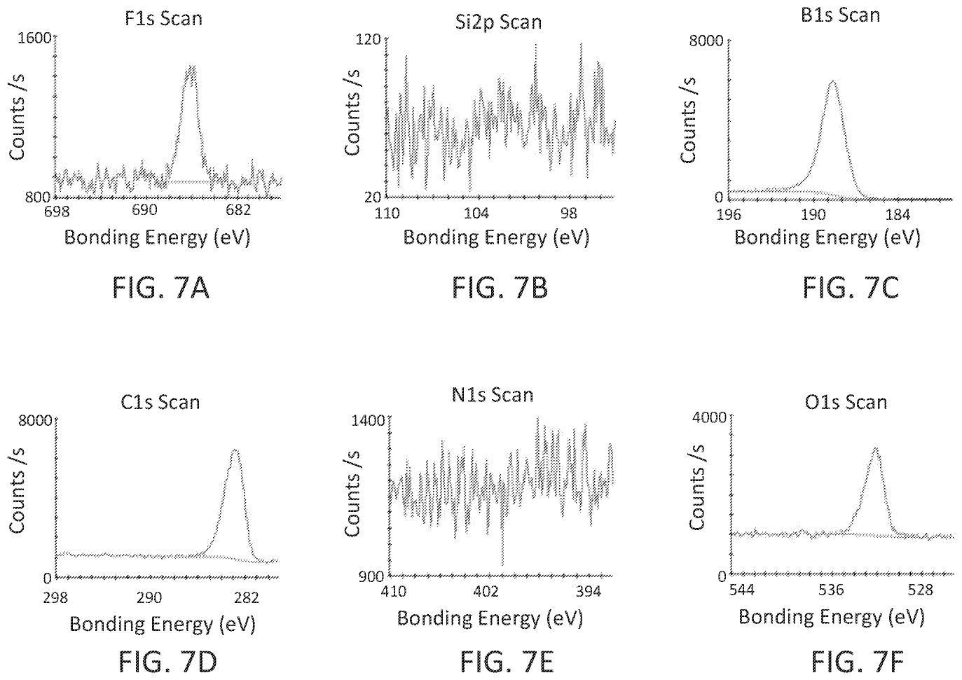

FIGS. 7A-7F illustrate XPS results related to a boron carbide film deposited according to another embodiment herein. For the sake of clarity, the film analyzed in connection with FIGS. 7A-7F is referred to as the “boron carbide film 2.” As compared to the boron carbide film 1 that was deposited at about 600° C., the boron carbide film 2 was deposited at a lower temperature of about 400° C. FIG. 7A shows the fluorine is scan, FIG. 7B shows the silicon 2p scan, FIG. 7C shows the boron 1s scan, FIG. 7D shows the carbon 1s scan, FIG. 7E shows the nitrogen Is scan, and FIG. 7F shows the oxygen is scan.

The XPS results in FIGS. 6A-6F and 7A-7F generally align with the FTIR/RBS/HFS results, which show a substantial amount of boron/carbon in the film, and much smaller amounts of other elements, as mentioned above. Generally, the results in FIGS. 6A-6F and 7A-7F reveal a simple bonding structure in the boron carbide films, in which B—C bonds are dominant, and little or no B—H and B—O bonds are observed. For example, the boron and carbon each show a single bonding state, indicating predominantly B—C bonding.

Table 2 shows the deposition temperature and the resulting hardness/Young's modulus for the two films described in this section.

TABLE 2

| | Deposition Temp | Hardness | Young's Modulus |
|---|---|---|---|
| Film | (° C.) | (GPa) | (GPa) |
| Boron Carbide Film 1 | 600 | 29 | 272 |
| Boron Carbide Film 2 | 400 | 25 | 223 |

While the boron carbide film 2, which was deposited at a lower temperature, showed lower hardness and Young's Modulus compared to the higher temperature boron carbide film 1, these properties were still within acceptable ranges for various desired applications such as hardmask applications. Notably, the hardness and Young's modulus were still substantially higher for the boron carbide films deposited according to the embodiments herein as compared to similar films deposited using conventional low temperature techniques that rely on the use of diborane.

Table 3 shows various properties of boron carbide film 1 and a similar boron carbide film deposited according to a conventional low temperature technique that relies on the use of diborane.

TABLE 3

| | | | Boron |
|---|---|---|---|
| | | Conventional | Carbide |
| Film Property | Test Method | boron carbide | Film 1 |
| Hardness (GPa) | Nanoindentation | 19.4 | 29 |
| Young's Modulus | Nanoindentation | 151 | 273 |
| (GPa) | | | |
| Hydrogen Content | HFS | 22 | 12.5 |
| (% atomic) | | | |
| Boron Content | RBS | 43 | 60.6 |
| (% atomic) | | | |
| Carbon Content | RBS | 30-40 | 25.8 |
| (% atomic) | | | |
| Fluorine Content | RBS, FTIR | n/a | <1% |
| (% atomic) | | | |
| Oxygen Content | RBS, FTIR | n/a | <1% |
| (% atomic) | | | |
| Density (g/cc) | x-ray | 1.85 | >2.2 |
| | reflectometry | | |
| | (XRR) | | |
| Crystallinity | XRD | amorphous | amorphous |
| Film Adhesion to | Tape test | Good/pass | Good/pass |
| silicon (1 μm | | | |
| thick layer) | | | |
| Moisture Uptake | FTIR (4 week | n/a | none |
| | queue time) | | |

The results in Table 3 indicate that the boron-based ceramic films formed according to embodiments herein may have substantially improved properties compared to conventionally deposited low temperature boron-based ceramic films that use diborane or other hydrogen- and boron-containing reactants. In various embodiments, a boron-based ceramic film deposited according to the embodiments herein may have any combination of the following properties: a hardness of about 20 GPa or greater, for example about 25 GPa or greater, a hardness of about 40 GPa or less, for example about 35 GPa or less, or about 30 GPa or less, or between about 25-30 GPa; a Young's modulus of about 175 GPa or greater, for example about 200 GPa or greater, or about 250 GPa or greater; a Young's modulus of about 400 GPa or less, for example about 350 GPa or less, or about 300 GPa or less; a hydrogen content of about 15% or less, for example about 13% or less; a boron content of about 50% or greater, for example about 60% or greater; a fluorine (or other halide) content of about 1% or less, for example about 0.75% or less; an oxygen content of about 1% or less, for example about 0.5% or less; and a density of about 2 g/cc or greater, for example about 2.2 g/cc or greater. Further, the boron-based ceramic film formed according to embodiments herein will typically show good adhesion to underlying silicon layers, and will show little or no moisture uptake, even after a wait time of about 4 weeks. As shown in Table 3, these properties are generally not achievable with conventional low temperature techniques. Further, as mentioned above, high temperature techniques for forming boron-based ceramic materials are often inappropriate for hardmask and similar semiconductor applications due to the limited thermal budget for such applications, as well as the high degree of crystallinity that typically results from the high temperature processes. As such, the techniques described herein provide excellent film properties, with substantial improvements over conventional techniques.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of forming a boron-based ceramic film on a substrate, the method comprising:
(a) receiving the substrate in a reaction chamber;
(b) providing a first reactant and a second reactant to the reaction chamber, the first reactant comprising a boron halide; and
(c) generating an inductively coupled plasma in the reaction chamber and reacting the first reactant with the second reactant in a plasma enhanced chemical vapor deposition reaction at a temperature of about 600° C. or less to form the boron-based ceramic film on the substrate.

2. The method of claim 1, wherein the boron-based ceramic film has a hydrogen content of about 15% (atomic) or less.

3. The method of claim 2, wherein the boron-based ceramic film has a halide content of about 1% (atomic) or less.

4. The method of claim 3, wherein the boron-based ceramic film has a Young's modulus of about 175 GPa or greater.

5. The method of claim 4, wherein the boron-based ceramic film has an oxygen content of about 1% (atomic) or less.

6. The method of claim 1, wherein the second reactant comprises a saturated or unsaturated hydrocarbon, and wherein the saturated or unsaturated hydrocarbon is the only hydrogen-bearing precursor provided to the reaction chamber.

7. The method of claim 1, wherein the first reactant comprises BF₃ and the second reactant comprises CH₄, and wherein the boron-based ceramic film comprises boron carbide having a composition of BₓC_{y}, where 2<x<4.5, and y=1.

8. The method of claim 1, wherein the boron-based ceramic film further comprises tungsten and/or silicon.

9. The method of claim 1, wherein a Young's modulus of the boron-based ceramic film is between about 250-300 GPa.

10. The method of claim 1, wherein a hardness of the boron-based ceramic film is about 20 GPa or greater.

11. The method of claim 1, wherein a hydrogen content of the boron-based ceramic film is about 13% (atomic) or less.

12. The method of claim 1, wherein a halide content of the boron-based ceramic film is about 0.75% (atomic) or less.

13. The method of claim 1, wherein a density of the boron-based ceramic film is about 2 g/cc or greater.

14. The method of claim 1, wherein the boron-based ceramic film has a boron content of about 50% (atomic) or greater.

15. The method of claim 1, wherein the first reactant comprises BF₃ and/or BCl₃.

16. The method of claim 1, wherein the first reactant comprises BBr₃ and/or BI₃.

17. The method of claim 1, wherein the second reactant comprises a reactant selected from the group consisting of: methane (CH₄), ethane (C₂H₆), propane (C₃H₈), ethene (C₂H₄), and propene (C₃H₆).

18. The method of claim 1, wherein the boron-based ceramic film is amorphous.

19. An apparatus for processing substrates, the apparatus comprising:
(a) a reaction chamber;
(b) a substrate support configured to support a substrate in the reaction chamber;
(c) one or more inlet for introducing reactants to the reaction chamber;
(d) one or more outlet for removing material from the reaction chamber; and
(e) a controller having at least one processor and a memory, wherein the at least one processor and the memory are communicatively connected with one another, and the memory stores computer-executable instructions for controlling the at least one processor to cause:
(i) exposing the substrate to an inductively coupled plasma to drive a plasma enhanced chemical vapor deposition reaction between a boron halide and an additional reactant to form a boron-based ceramic film on the substrate at a temperature of about 600° C. or less.

20. An apparatus for forming a boron-based ceramic film on a substrate, the apparatus comprising:
(a) a reaction chamber;
(b) a substrate support configured to support the substrate in the reaction chamber;
(c) one or more inlet for introducing reactants to the reaction chamber;
(d) one or more outlet for removing material from the reaction chamber;
(e) a plasma generator configured to generate a plasma in the reaction chamber, the plasma being an inductively coupled plasma; and
(f) a controller having at least one processor and a memory, wherein the at least one processor and the memory are communicatively connected with one another, and the memory stores computer-executable instructions for controlling the at least one processor to cause:
(i) receiving the substrate in the reaction chamber,
(ii) flowing a first reactant and a second reactant into the reaction chamber, and
(iii) generating the plasma in the reaction chamber and reacting the first reactant with the second reactant at a temperature of about 600° C. or less to form the boron-based ceramic film on the substrate, wherein the boron-based ceramic film has:
(1) a Young's modulus of about 175 GPa or greater,
(2) a hydrogen content of about 15% (atomic) or less, and
(3) a halide content of about 1% (atomic) or less.
